(19) United States
(12) Patent Application Publication
(10) Pub. No.: US 2011/0253214 A1
(43) Pub. Date: Oct. 20, 2011

(54) ELECTRICITY GENERATING APPARATUS USING SOLAR POWER

(75) Inventor: Chun-Neng Chung, Pingtung County (TW)

(73) Assignee: FUNG GIN DA ENERGY SCIENCE AND TECHNOLOGY CO., LTD., Pingtung (TW)

(21) Appl. No.: 12/795,881

(22) Filed: Jun. 8, 2010

(30) Foreign Application Priority Data
Apr. 16, 2010 (TW) 099112015

(51) Int. Cl. H01L 31/00

(52) U.S. Cl. 136/259

(57) ABSTRACT

An electricity generating apparatus using solar power includes a supporting device for supporting movably a solar power collecting unit that includes a solar power collecting plate carried on a carrier for converting solar power into electrical energy, and a condensing unit mounted on the carrier and disposed above the solar power collecting plate. The supporting device includes a disk member mounted rotatably on a top side of a hollow base body and driven by a drive unit in the base body to rotate relative to the base body in a central axis of the disk member, and a telescopic rod member and two upright supporting rods interconnecting said carrier and the disk member. A control module controls the drive unit and the telescopic rod member based on a solar radiating direction such that the power solar collecting plate is moved to face sunlight.

### BACKGROUND OF THE INVENTION

1. Field of the Invention

The invention relates to an electricity generating apparatus, and more particularly to an electricity generating apparatus using solar power.

2. Description of the Related Art

FIG. 1 illustrates a conventional electricity generating device using solar power disclosed in Taiwanese Patent Publication No. M279834. The conventional electricity generating device includes: a carrier 12 for carrying a solar power collecting plate 11 thereon; a sensing unit mounted on the carrier 12 and having a plurality of sensors 15 for sensing a solar radiating direction; a driver 13 for driving movement of the carrier 12; and a controller 14 for controlling the driver based on a sensing result made by the sensing unit such that the solar power collecting plate 11 is moved to thereby increase a solar power collecting efficiency.

However, when sunlight becomes weak, the conventional electricity generating device has a decreased solar power collecting efficiency. Therefore, the conventional electricity generating device cannot ensure stable generation of electricity.

### SUMMARY OF THE INVENTION

Therefore, an object of the present invention is to provide an electricity generating apparatus using solar power that can overcome the aforesaid disadvantages of the prior art.

According to the present invention, an electricity generating apparatus using solar power comprises:

a solar power collecting unit including
a carrier,
a solar power collecting plate carried on the carrier for converting solar power into electrical energy, and
a condensing unit mounted on the carrier and disposed above the solar power collecting plate for concentrating sunlight onto the solar power collecting plate;

a supporting device operable to support movably the solar power collecting unit on a supporting surface, the supporting device including
a hollow base body adapted to be disposed on the supporting surface and having a top side,
a disk member mounted rotatably on the top side of the base body such that the disk member is rotatable relative to the base body about a central axis of the disk member that is transverse to the supporting surface,
a drive unit disposed in the base body for driving rotation of the disk member about the central axis,
a telescopic rod member having opposite upper and lower pivot ends connected pivotally and respectively to the carrier and the disk member, and
two upright supporting rods spaced apart from each other, each of the supporting rods having a lower end fixed on the disk member, and an upper end opposite to the lower end and connected pivotally to the carrier; and

a control module including
a sensing unit for generating a sensing output indicating a solar radiating direction, and
a controller coupled to the sensing unit, the drive unit and the telescopic rod member, receiving the sensing output from the sensing unit, and operable to control the drive unit and the telescopic rod member based on the sensing output received thereby such that the solar power collecting plate is moved to face sunlight in response to rotation of the disk member driven by the drive unit and adjustment of the telescopic rod member in length.

### BRIEF DESCRIPTION OF THE DRAWINGS

Other features and advantages of the present invention will become apparent in the following detailed description of the preferred embodiments with reference to the accompanying drawings, of which:

FIG. 1 is a fragmentary schematic side view of a conventional electricity generating device using solar power;

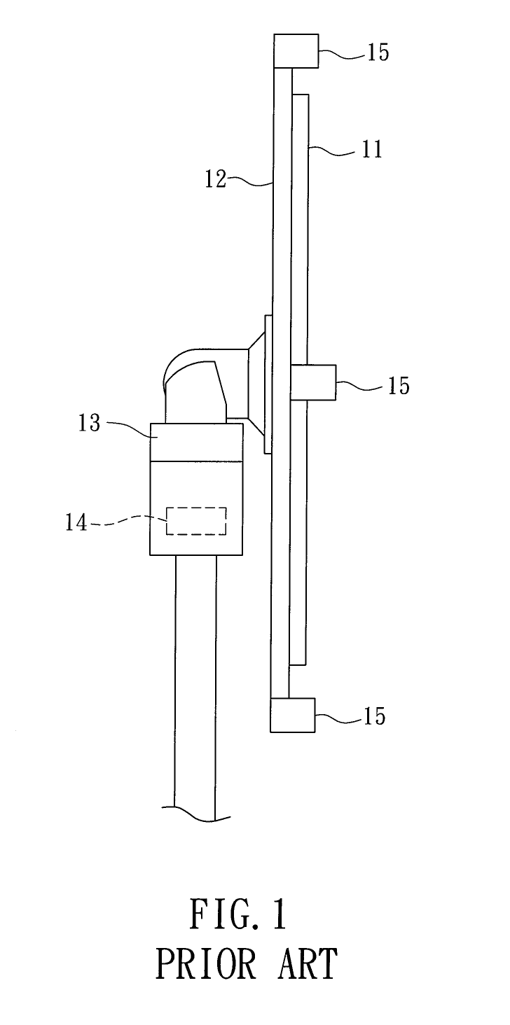

FIG. 2 is a perspective view showing the first preferred embodiment of an electricity generating apparatus using solar power according to the present invention;

FIG. 3 is a fragmentary, partly schematic sectional view showing the first preferred embodiment when operated in a state of use;

FIG. 4 is a schematic circuit block diagram illustrating the first preferred embodiment;

FIG. 5 is a perspective view showing a solar power collecting unit of the first preferred embodiment;

FIG. 6 is a fragmentary, partly schematic sectional view showing the solar power collecting unit of the first preferred embodiment;

FIG. 7 is a fragmentary, partly schematic sectional view illustrating rotation of condenser lenses of the solar power collecting unit of the first preferred embodiment;

FIG. 8 is a fragmentary, partly schematic sectional view illustrating a variation of the condenser lenses of the solar power collecting unit of the first preferred embodiment;

FIG. 9 is a fragmentary schematic sectional view showing the first preferred embodiment when operated in another state of use; and

FIG. 10 is a schematic sectional view showing the second preferred embodiment of an electricity generating apparatus using solar power according to the present invention.

### DETAILED DESCRIPTION OF THE PREFERRED EMBODIMENTS

Before the present invention is described in greater detail, it should be noted that like elements are denoted by the same reference numerals throughout the disclosure.

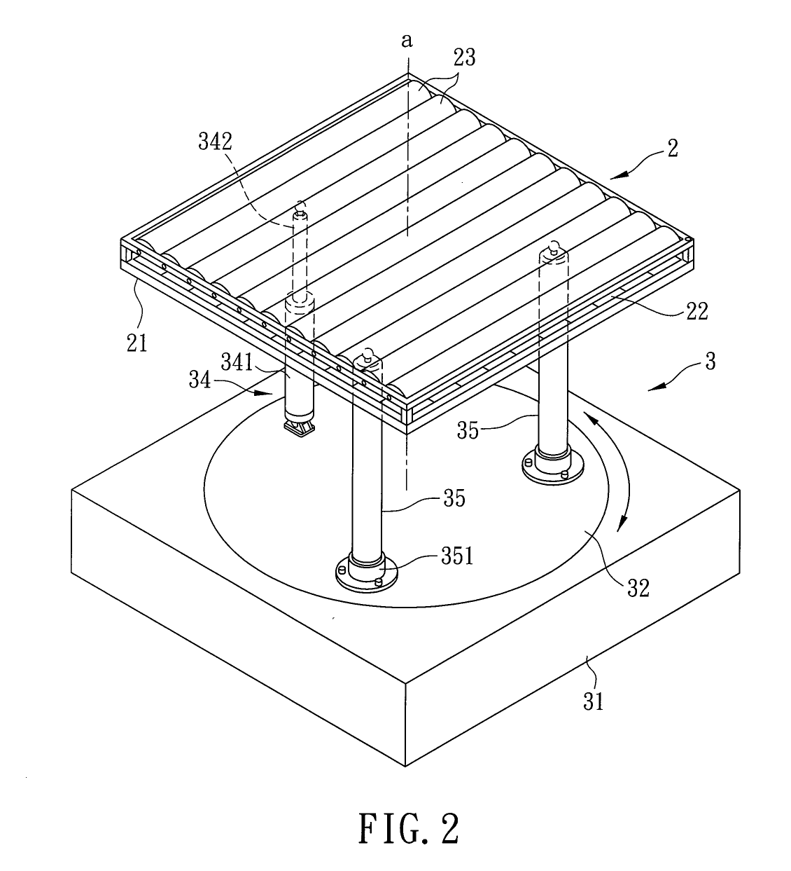

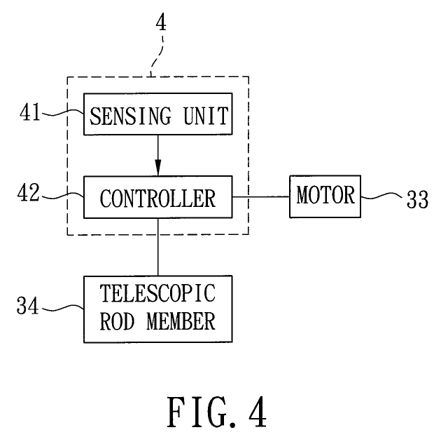

Referring to FIGS. 2 to 4, the first preferred embodiment of an electricity generating apparatus using solar power according to the present invention is shown to include a solar power collecting unit 2, a supporting device 3, and a control module 4.

The solar power collecting unit 2 includes a carrier 21, a solar power collecting plate 22, a condensing unit and an energy storing member 24.

The solar power collecting plate 22, such as a solar panel, is carried on the carrier 21 for converting solar power into electrical energy.

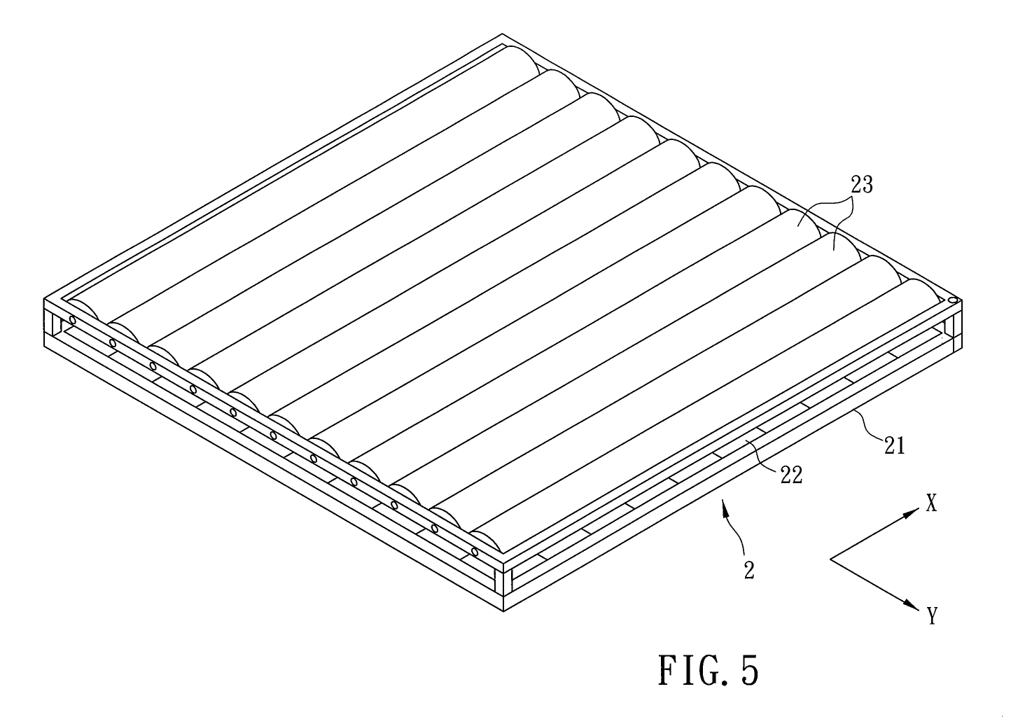

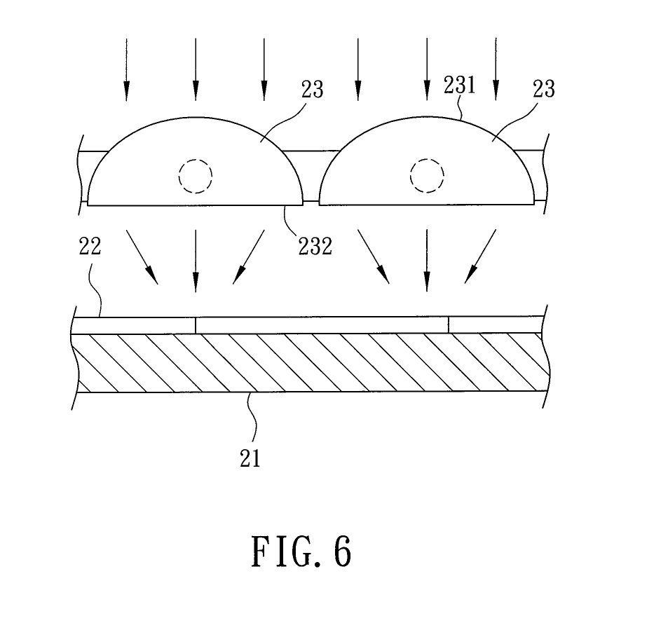

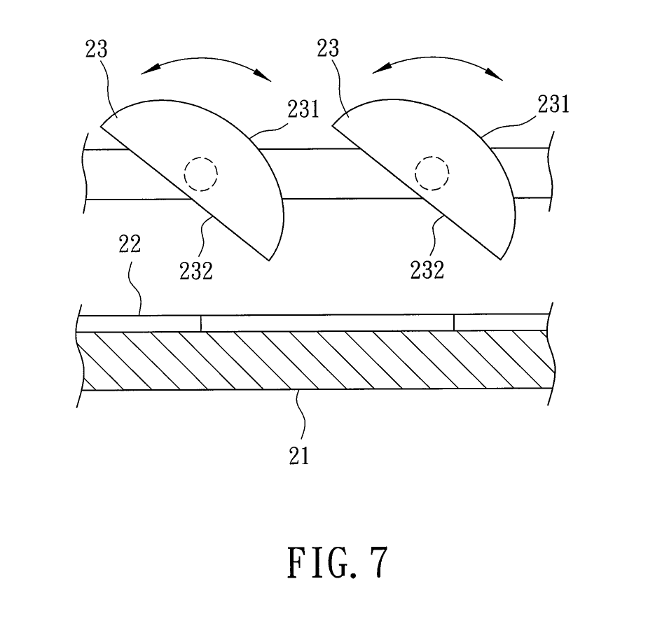

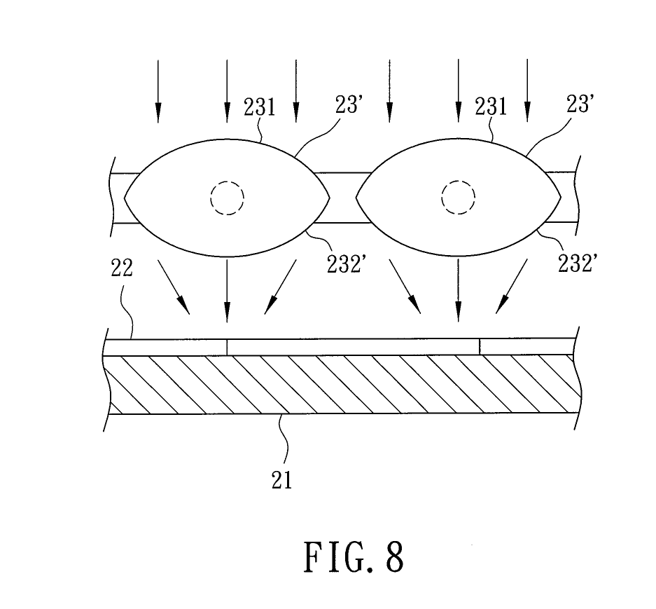

The condensing unit is mounted on the carrier 21 and includes a plurality of condenser lenses 23 disposed above the solar power collecting plate 22 for concentrating sunlight onto the solar power collecting plate 22 (see FIG. 6). The condenser lenses 23 extend in a first direction (X), and are arranged in a second direction (Y) transverse to the first direction (X), as shown in FIG. 5. The condenser lenses 23 are mounted rotatably on the carrier 21 such that each condenser lens 23 is rotatable relative to the carrier 21, as shown in FIG. 7. In this embodiment, each condenser lens 23 has a convex surface 231, and a flat surface 232 opposite to said convex surface 231 and facing the solar power collecting plate 22, as shown in FIG. 6. In other embodiments, as shown in FIG. 8, each condenser lens 23′ has opposite convex surfaces 231, 232′, wherein the convex surface 232′ of each condenser lens 23′ faces the solar power collecting plate 22.

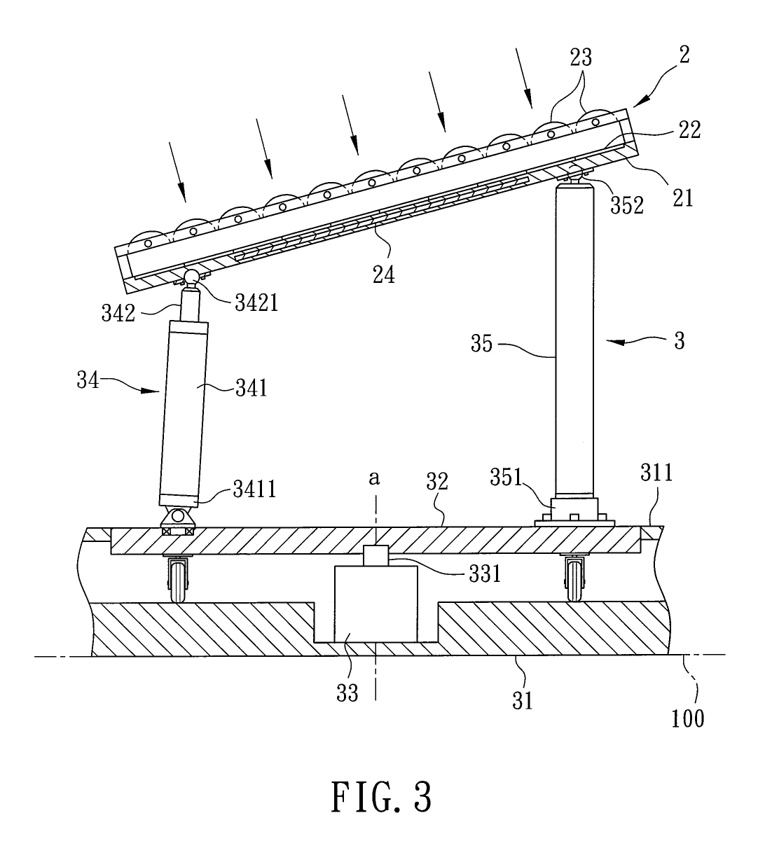

The energy storing member 24 is connected to the solar power collecting plate 23 for storing electrical energy therefrom. In this embodiment, the energy storing member 24 is mounted in the carrier 21, and is disposed below the solar power collecting plate 22, as shown in FIG. 3.

The supporting device 3 is operable to support movably the solar power collecting unit 2 on a supporting surface 100. The supporting device 3 includes a hollow base body 31, a disk member 32, a drive unit 33, a telescopic rod member 34, and two upright supporting rods 35.

In this embodiment, the base body 31 is adapted to be disposed on the supporting surface 100 and has a top side 311.

The disk member 32 is mounted rotatably on the top side 311 of the base body 31 such that the disk member 32 is rotatable relative to the base body 31 about a central axis (a) of the disk member 32 that is transverse to the supporting surface 100.

The drive unit is disposed in the base body 31 for driving rotation of the disk member 32 about the central axis (a). In this embodiment, as shown in FIG. 3, the drive unit includes a motor 33 having a drive shaft 331 extending along the central axis (a) and fixed on the disk member 32 such that the disk member 32 is co-rotatable with the drive shaft 331 of the motor 33.

In this embodiment, the telescopic rod member 34 is in the form of a fluid cylinder, such as an oil cylinder or a pneumatic cylinder. The telescopic rod member 34 has a cylinder body 341, and a piston rod 342 coupled movably to the cylinder body 341. The cylinder body 341 has a lower pivot end 3411 connected pivotally to the disk member 32. The piston rod 342 has an upper pivot end 3421 connected pivotally to the carrier 21 of the solar power collecting unit 2.

The supporting rods 35 are spaced apart from each other. Each supporting rod 35 has a lower end 351 fixed on the disk member 32, and an upper end 352 opposite to the lower end 351 and connected pivotally to the carrier 21.

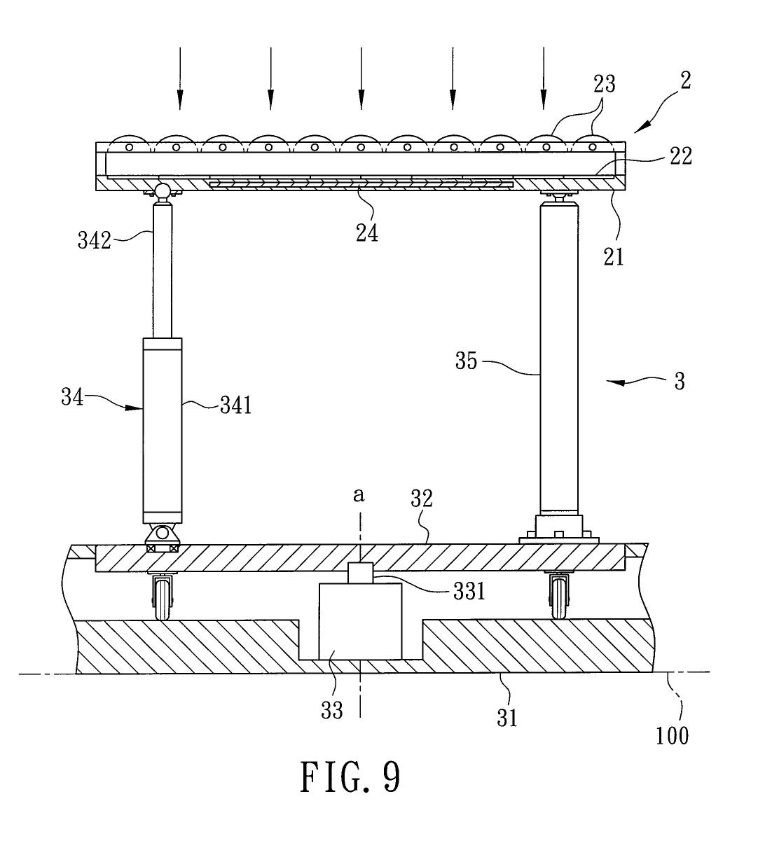

The control module 4 includes a sensing unit 41 and a controller 42. The sensing unit 41 generates a sensing output indicating a solar radiating direction. The controller 42 is coupled to the sensing unit 41, the motor 33 of the drive unit and the telescopic rod member 34. The controller 42 receives the sensing output from the sensing unit 41, and is operable to control the motor 33 of the drive unit and the telescopic rod member 34 based on the sensing output received thereby such that the solar power collecting plate 22 is moved to face sunlight in response to rotation of the disk member 32 driven by the motor 33 of the drive unit and adjustment of the telescopic rod member 34 in length, as shown in FIGS. 3 and 9.

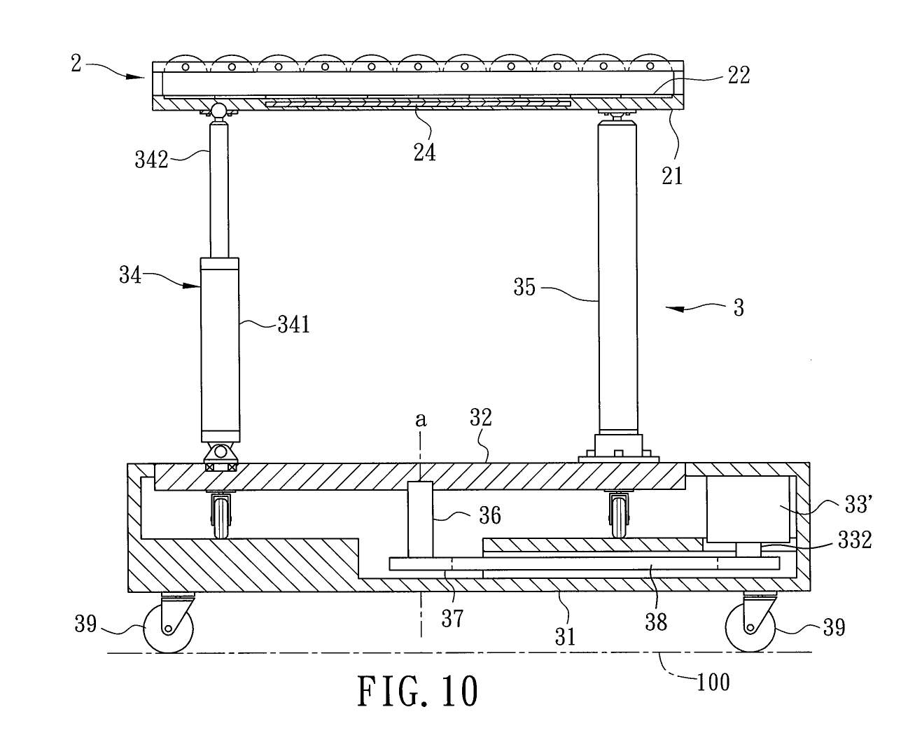

FIG. 10 illustrates the second preferred embodiment of an electricity generating apparatus using solar power according to this invention, which is a modification of the first preferred embodiment. In this embodiment, the drive unit includes a motor 33′, a drive rod 36, a transmission wheel 37 and a looped transmission belt 38. The motor 33′ is connected electrically to and control led by the controller 42 of the control module 4, and has a motor shaft 332. The drive rod 36 extends along the central axis (a), and is fixed on the disk member 32 such that the disk member 32 is co-rotatable with the drive rod 36. The transmission wheel 37 is mounted on and is co-rotatable with the drive rod 36. The transmission belt 38 is trained on the motor shaft 332 of the motor 332 and the transmission wheel 37.

Furthermore, the supporting device 3 further includes a plurality of wheels 39 mounted on a bottom side of the base body 31 such that the base body 31 is movable relative to the supporting surface 100.

In sum, due to the presence of the sensing unit 41, the supporting device 3 can be appropriately controlled by the controller 42 such that the solar power collecting plate 22 is moved to face sunlight. Furthermore, the condenser lenses 23 can be operated to effectively concentrate sunlight onto the solar power collecting plate 22. Therefore, the electricity generating apparatus of the present invention can achieve an enhanced solar power collecting efficiency, thereby ensuring stable electric generation.

While the present invention has been described in connection with what are considered the most practical and preferred embodiments, it is understood that this invention is not limited to the disclosed embodiments but is intended to cover various arrangements included within the spirit and scope of the broadest interpretation so as to encompass all such modifications and equivalent arrangements.

What is claimed is:

1. An electricity generating apparatus using solar power, comprising:
a solar power collecting unit including
a carrier,
a solar power collecting plate carried on said carrier for converting solar power into electrical energy, and
a condensing unit mounted on said carrier and disposed above said solar power collecting plate for concentrating sunlight onto said solar power collecting plate;
a supporting device operable to support movably said solar power collecting unit on a supporting surface, said supporting device including
a hollow base body adapted to be disposed on the supporting surface and having a top side,
a disk member mounted rotatably on said top side of said base body such that said disk member is rotatable relative to said base body about a central axis of said disk member that is transverse to the supporting surface,
a drive unit disposed in said base body for driving rotation of said disk member about the central axis,
a telescopic rod member having opposite upper and lower pivot ends connected pivotally and respectively to said carrier and said disk member, and
two upright supporting rods spaced apart from each other, each of said supporting rods having a lower end fixed on said disk member, and an upper end opposite to said lower end and connected pivotally to said carrier; and
a control module including
a sensing unit for generating a sensing output indicating a solar radiating direction, and
a controller coupled to said sensing unit, said drive unit and said telescopic rod member, receiving the sensing output from said sensing unit, and operable to control said drive unit and said telescopic rod member based on said sensing output received thereby such that said solar power collecting plate is moved to face sunlight in response to rotation of said disk member driven by said drive unit and adjustment of said telescopic rod member in length.

2. The electricity generating apparatus as claimed in claim 1, wherein said solar power collecting unit further includes an energy storing member connected electrically to said solar power collecting plate for storing electrical energy therefrom.

3. The electricity generating apparatus as claimed in claim 2, wherein said energy storing member is mounted in said carrier and disposed below said solar power collecting plate.

4. The electricity generating apparatus as claimed in claim 1, wherein said condensing unit includes a plurality of condenser lenses extending in a first direction, arranged in a second direction transverse to the first direction, and mounted rotatably on said carrier.

5. The electricity generating apparatus as claimed in claim 4, wherein each of said condenser lenses of said condensing unit has a convex surface, and a flat surface opposite said convex surface and facing said solar power collecting plate.

6. The electricity generating apparatus as claimed in claim 4, wherein each of said condenser lenses of said condensing unit has opposite convex surfaces.

7. The electricity generating apparatus as claimed in claim 1, wherein said telescopic rod member of said supporting device is in the form of a fluid cylinder.

8. The electricity generating apparatus as claimed in claim 1, wherein said drive unit includes a motor connected electrically to and controlled by said controller of said control module, and having a drive shaft extending along the central axis and fixed on said disk member such that said disk member is co-rotatable with said drive shaft of said motor.

9. The electricity generating apparatus as claimed in claim 1, wherein said drive unit includes:
a motor connected electrically to and controlled by said controller of said control module, and having a motor shaft;
a drive rod extending along the central axis, and fixed on said disk member such that said disk member is co-rotatable with said drive rod;
a transmission wheel mounted on and co-rotatable with said drive rod; and
a looped transmission belt trained on said motor shaft of said motor and said transmission wheel.

10. The electricity generating apparatus as claimed in claim 1, wherein said supporting device further includes a plurality of wheels mounted on a bottom side of said base body such that said base body is movable relative to the supporting surface.
